(19) United States
(12) Patent Application Publication
(10) Pub. No.: US 2011/0001211 A1
(43) Pub. Date: Jan. 6, 2011

(54) FUSE FOR IN USE OF A SEMICONDUCTOR DEVICE AND METHOD FOR FORMING THE SAME

(75) Inventor: Byung Wook BAE, Icheon-si (KR)

Correspondence Address: AMPACC Law Group, PLLC, 6100 219th Street SW, Suite 580, Mountlake Terrace, WA, 98043, US

(73) Assignee: Hynix Semiconductor Inc., Icheon-si (KR)

(21) Appl. No.: 12/641,032

(22) Filed: Dec. 17, 2009

(30) Foreign Application Priority Data
Jul. 6, 2009 (KR) 10-2009-0061057

(51) Int. Cl. H01L 23/525; H01L 21/768

(52) U.S. Cl. 257/529; 438/601; 257/E23.149; 257/E21.592

(57) ABSTRACT

Provided is a fuse of a semiconductor device that includes a Y type fuse and an insulation layer configured to expose the Y type fuse such that an exposed portion of the Y type fuse has a substantially ‘V’ shape. According to the present invention, metal crack is prevented from occurring in a Y type fuse under a high temperature and high humidity condition of a reliability test so that the reliability and competitiveness of semiconductor devices can be improved.

### CROSS-REFERENCES TO RELATED APPLICATIONS

The present application claims priority to Korean patent application number 10-2009-0061057 filed on Jul. 6, 2009, which is incorporated by reference in its entirety.

### BACKGROUND OF THE INVENTION

The present invention relates to a fuse of a semiconductor device and a method of forming the same, more particularly, to a Y type fuse having an improved reliability under a high temperature and high humidity condition and a method of forming the same.

A semiconductor device such as, for example, a memory device or a memory merged logic (MML) memory device includes a plurality of memory cells for storing a data. If a defect occurs in one of the memory cells, the semiconductor device is discarded as an inferior product, thereby reducing a production yield. However, it is very inefficient yield-wise to discard the entire device for having few defective cells in the memory. Therefore, in order to secure a high yield of the semiconductor device having the memory device or the memory, a repair process needs to be performed. Generally, a redundancy memory cell is used to replace a defective cell in the repair process. Here, a fuse, which can be blown, is used to replace the defective memory cell with the redundancy memory cell. After the semiconductor device is tested, the fuses are selectively cut off according to a test result.

Generally, the repair method using the redundancy cell includes installing a redundancy word line and a redundancy bit line beforehand and replacing a normal word line having a defect with the redundancy word line or a normal bit line having a defect with the redundancy bit line which is disposed in each cell array. To this end, the memory device includes a circuit for replacing an address of a defective cell identified through a test after wafer processing with an address of a redundancy cell. Thus, when an address signal corresponding to the defective cell is inputted, a data in the corresponding redundancy cell substituting the defective cell is accessed.

The most commonly used method to perform the above repair process is a fuse blowing in which a laser beam is irradiated into a corresponding fuse to cut the fuse, thereby replacing the corresponding address with an address signal of a redundancy cell. Therefore, the memory device typically includes a fuse unit for irradiating a laser into the fuse to blow the fuse so that the corresponding address can be substituted. Here, a wire disconnected by laser irradiation is referred to as a fuse, and the disconnected site and its surrounding region are referred to as a fuse box. The fuse includes an I type fuse, which blows once in one fuse box, and a Y type fuse, which has a double blowing mechanism in one fuse box.

Meanwhile, a reliability test is performed on the semiconductor device that passes an electronic test. Here, the reliability test is performed by applying a normal level of DC power to the device, leaving the device for a longer period of time under a high temperature and high humidity condition, and testing characteristics thereof. Here, a metal crack is found only in the Y type fuse under the high temperature and high humidity condition.

More specifically, in a typical package process of a semiconductor device, an epoxy material having high cohesion is used for coating the fuse prior to coating the fuse with a hard material, and thus, the fuse is covered with the epoxy material having the high cohesion. The epoxy material is a semi-liquid material so that reflow occurs under the high temperature and high humidity condition. Here, stress generated due to the reflow is directly conveyed to the fuse, and, in case of the Y type fuse in which an exposed portion to an external is about twice that of the I type fuse, more stress is applied to the Y type fuse, thereby causing metal to crack.

Therefore, an erroneous operation of the fuse may occur such that the fuse which is not actually blown operates as if the fuse is blown and cut off.

### BRIEF SUMMARY OF THE INVENTION

Embodiments of the present invention are directed to overcoming the problem associated with cracking in metal in a Y type fuse when performing a reliability test of a device under a high temperature and high humidity so that the fuse operates as if it is blown.

According to one aspect of the present invention, a fuse of a semiconductor device includes a Y type fuse, and an insulation layer configured to expose the Y type fuse such that an exposed portion of the Y type fuse has a substantially ‘V’ shape.

Preferably, the exposed portion having the substantially ‘V’ shape corresponds to an area in which a fuse blowing occurs.

Preferably, the Y type fuse includes an upper fuse interconnection, a lower fuse interconnection, and a fuse contact connected to a lower part of the upper fuse interconnection and an upper part of the lower fuse interconnection.

Preferably, the upper fuse interconnection has a ‘V’ shape and the lower fuse interconnection has a ‘T’ shape.

Preferably, the upper fuse interconnection has a ‘T’ shape and the lower fuse interconnection has a ‘V’ shape.

Preferably, the fuse of the semiconductor device further includes a lower interconnection positioned on a substantially same plane with the lower fuse interconnection.

Preferably, a metal interconnection is positioned below the lower fuse interconnection.

Preferably, the fuse of the semiconductor device further includes a first lower contact positioned between the lower fuse interconnection and the metal interconnection.

Preferably, the Y type fuse includes a ‘V’ shaped area and a ‘T’ shaped area, the ‘V’ shaped area being projected by a step difference and the ‘T’ shaped area being positioned lower than the ‘V’ shaped area by the step difference.

Preferably, the fuse of the semiconductor device further includes a metal interconnection positioned below the Y type fuse.

Preferably, the fuse of the semiconductor device further includes a second lower contact that is connected to a lower part of the Y type fuse and an upper part of the metal interconnection.

According to another aspect of the present invention, a method of forming a fuse of a semiconductor device includes forming a Y type fuse and forming an insulation layer on the Y type fuse that exposes the Y type fuse such that an exposed portion of the Y type fuse has a substantially ‘V’ shape.

Preferably, the method further includes, after forming the insulation layer, blowing the Y type fuse that is exposed in the substantially ‘V’ shape.

Preferably, the forming the Y type fuse includes forming a lower fuse interconnection, forming a fuse contact on the lower fuse interconnection, and forming an upper fuse interconnection that is connected to an upper part of the fuse contact.

Preferably, in the forming the insulation layer, the upper fuse interconnection is exposed such that an exposed portion of the upper fuse interconnection has a substantially ‘V’ shape.

Preferably, in the forming the insulation layer, the lower fuse interconnection is exposed such that an exposed portion of the lower fuse interconnection has a substantially ‘V’ shape.

Preferably, the method further includes, at the same time as the forming the lower fuse interconnection, forming a lower interconnection that is on a substantially same plane with the lower fuse interconnection.

Preferably, the method further includes, prior to the forming the lower fuse interconnection, forming a metal interconnection and forming a first lower contact on the metal interconnection, the first lower contact being connected with the lower fuse interconnection and the lower interconnection.

Preferably, the forming the Y type fuse includes forming an interlayer insulation layer having a step difference and forming a fuse interconnection on the interlayer insulation layer.

Preferably, the method further includes, prior to the forming the Y type fuse, forming a metal interconnection and forming a second lower contact on the metal interconnection, the second lower contact being connected with the Y type fuse.

According to the present invention, metal crack is prevented from occurring in the Y type fuse under the high temperature and high humidity condition of the reliability test so that the reliability and competitiveness of semiconductor devices can be improved.

### BRIEF DESCRIPTION OF THE DRAWINGS

FIG. 1a (i) is a plan view of a fuse according to an embodiment of the present invention and FIG. 1a (ii) is a cross-sectional view of the fuse according to the embodiment of the present invention.

FIGS. 1b through 1d are cross-sectional views illustrating a method of forming a fuse according to an embodiment of the present invention.

FIG. 2a (i) is a plan view of a fuse according to another embodiment of the present invention and FIG. 2a (ii) is a cross-sectional view of the fuse according to another embodiment of the present invention.

FIGS. 2b through 2e are cross-sectional views illustrating a method of forming a fuse according to another embodiment of the present invention.

FIG. 3a (i) is a plan view of a fuse according to still another embodiment of the present invention and FIG. 3a (ii) is a cross-sectional view of the fuse according to still another embodiment of the present invention.

FIGS. 3b through 3d are cross-sectional views illustrating a method of forming a fuse according to still another embodiment of the present invention.

### DESCRIPTION OF EMBODIMENTS

Hereinafter, the example embodiments of the present invention will be described in detail with reference to the accompanying drawings.

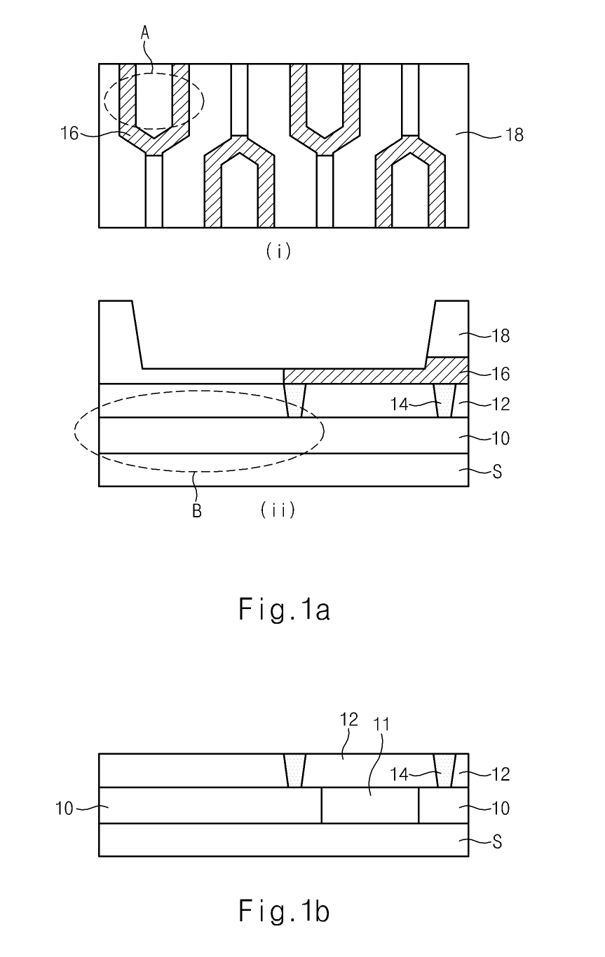

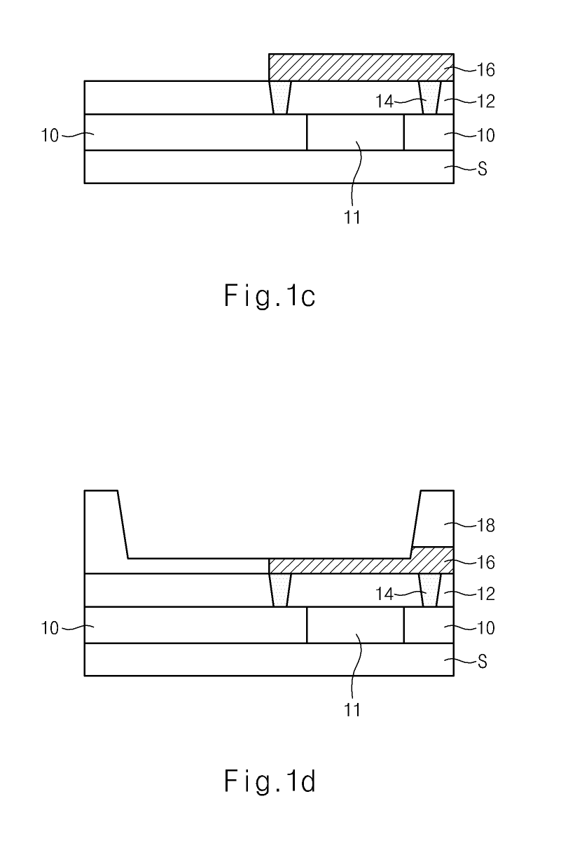

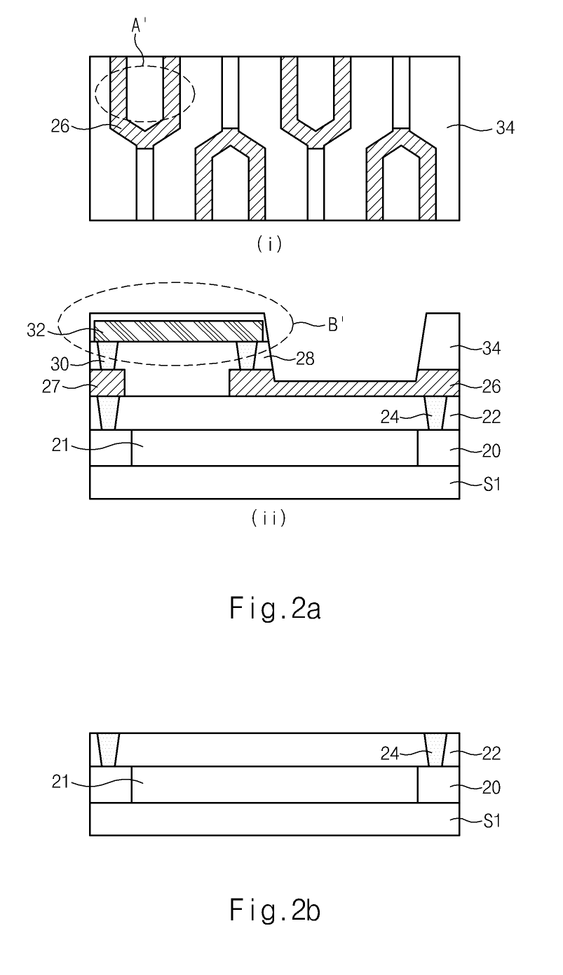

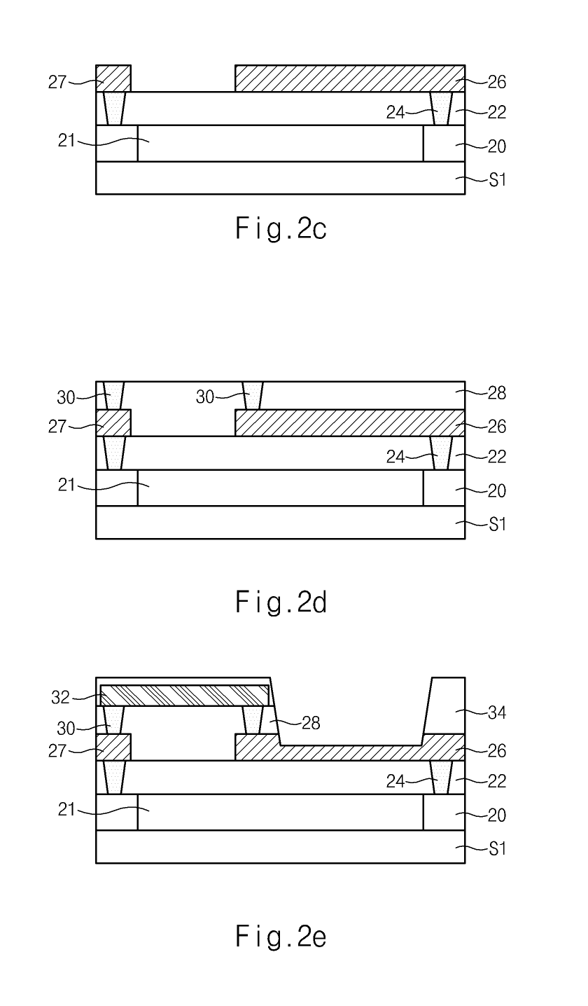

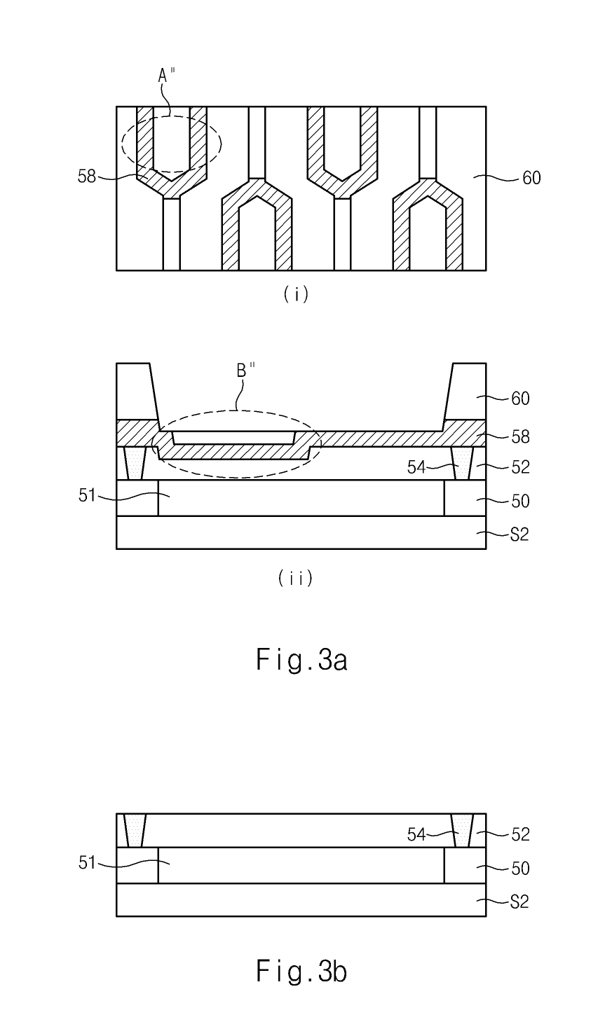

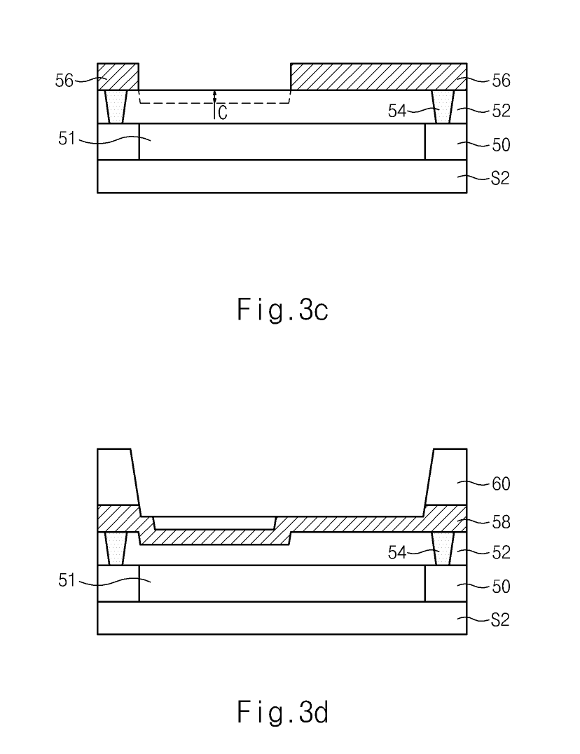

FIG. 1a (i) is a plan view of a fuse according to an embodiment of the present invention and FIG. 1a (ii) is a cross-sectional view of the fuse according to an embodiment of the present invention. FIGS. 1b through 1d are cross-sectional views illustrating a method of forming a fuse according to an embodiment of the present invention. FIG. 2a (i) is a plan view of a fuse according to another embodiment of the present invention and FIG. 2a (ii) is a cross-sectional view of the fuse according to another embodiment of the present invention. FIGS. 2b through 2e are cross-sectional views illustrating a method of forming a fuse according to another embodiment of the present invention. FIG. 3a (i) is a plan view of a fuse according to still another embodiment of the present invention and FIG. 3a (ii) is a cross-sectional view of the fuse according to still another embodiment of the present invention. FIGS. 3b through 3d are cross-sectional views illustrating a method of forming a fuse according to still another embodiment of the present invention.

As illustrated in FIG. 1a, the fuse according to the present invention has a Y type double level interconnection structure including a fuse contact. More specifically, the Y type double level interconnection structure includes an upper fuse interconnection 16, a lower fuse interconnection 10, and a fuse contact 14 for connecting the upper fuse interconnection 16 and the lower fuse interconnection 10. Here, the upper fuse interconnection 16 preferably has a ‘V’ shape and the lower fuse interconnection 10 preferably has a ‘T’ shape. The upper fuse interconnection 16 is an area in which an actual blowing occurs.

Namely, when blowing the fuse, a laser is applied only to a ‘V’ shaped area A that is divided into two forks the fuse so that the lower fuse interconnection 10 having the ‘T’ shape does not need to be exposed for blowing purposes. Thus, the lower fuse interconnection 10 is electrically connected to the upper fuse interconnection 16 through the fuse contact 14, which is electrically connected to a lower part of the upper fuse interconnection 16.

Also, the lower fuse interconnection 10 is positioned to be lower than the fuse contact 14 so that the lower fuse interconnection 10 is not on the same plane with the upper fuse interconnection 16. In this way, the lower fuse interconnection 10, shown in an area B, is not exposed when the fuse blows. By exposing only the upper fuse interconnection 16 in which an actual fuse blowing occurs, the fuse does not receive a stress imposed by a reflowing epoxy in a high temperature and high humidity environment, thereby avoiding the occurrence of metal cracking. As a result, a blowing area remains the same with the related art and a power supply is provided through the fuse contact 14, thereby operating in the same way as the conventional Y type fuse. Also, since the Y type fuse having the double level interconnection structure has only the upper fuse interconnection 16 to be exposed, a length of an interconnection exposed is reduced to half so that cracking of metal can be prevented from occurring due to strong stress in a high temperature and high humidity environment of the reliability test.

The above described fuse of the semiconductor device can be performed by the following method.

As shown in FIG. 1b, a metal layer formed over a semiconductor substrate S is patterned to form the lower fuse interconnection 10. Next, an interlayer insulation layer 11 is formed on the lower fuse interconnection 10, and a planarization etching process is performed on the interlayer insulation layer 11 so that the lower fuse interconnection 10 is exposed. Next, an interlayer insulation layer 12 is formed over the lower fuse interconnection 10 and the interlayer insulation layer 11 and a contact hole (not shown) is formed on the interlayer insulation layer 12. A conductive material (not shown) is formed over an overall upper surface such that the contact hole (not shown) is filled with the conductive material, and a planarizing process is performed on the conductive material (not shown) to expose the interlayer insulation layer 12 to form the fuse contact 14.

As illustrated in FIG. 1c, an upper fuse metal (not shown) is formed over an entire upper surface, and a photoresist pattern (not shown) is formed on the upper fuse metal (not shown), which is then etched by an etch mask to form the upper fuse interconnection 16. Here, the upper fuse interconnection 16 is preferably connected to an upper part of the fuse contact 14.

As illustrated in FIG. 1d, when an insulation layer 18 is formed over an entire upper surface including the upper fuse interconnection 16, the insulation layer 18 is etched to expose the upper fuse interconnection 16 such that an area in which blowing occurs is exposed. Although not shown in the drawing, the laser is applied to the upper fuse interconnection 16 when blowing the fuse.

As described above, in order to achieve the object of the present invention, the Y type fuse has a length that is substantially similar to that of the I type fuse in order to secure reliability under a high temperature and high humidity environment. Therefore, it should be noted that the object of the present invention can be achieved in many alternative ways other than the method described with reference to FIGS. 1a through 1d. Hereinafter, the fuse of the semiconductor device and the method of forming the same according to different embodiments will be described.

As illustrated in FIG. 2a, the fuse according to another embodiment of the present invention includes the Y type double level interconnection structure including a fuse contact.

More specifically, the Y type double level interconnection structure includes an upper fuse interconnection 32, a lower fuse interconnection 26, and a fuse contact 30 for connecting the upper fuse interconnection 32 and the lower fuse interconnection 26. Here, the Y type double level interconnection structure further includes a lower contact 24, which is connected to a lower part of the lower fuse interconnection 26, and a metal interconnection 20, which is connected to a lower part of the lower contact 24. Here, the upper fuse interconnection 32 preferably has a ‘T’ shape and the lower fuse interconnection 26 preferably has a ‘V’ shape. The lower fuse interconnection 26 is an area in which the actual fuse blowing occurs. Namely, when blowing the fuse, the laser is applied only to a ‘V’ shaped area A′ that is divided into two forks so that the upper fuse interconnection 32 having the ‘T’ shape does not need to be exposed for blowing purposes.

Thus, the upper fuse interconnection 32 is electrically connected to the lower fuse interconnection 26 through the fuse contact 30, which is electrically connected to a first side of an upper part of the upper fuse interconnection 16. Also, the upper fuse interconnection 32 is positioned on the fuse contact 30, as shown in an area B,′ so that the upper fuse interconnection 32 is not on the same plane with the lower fuse interconnection 26. In this way, only the lower fuse interconnection 26 in which the actual fuse blowing occurs is exposed so that the fuse does not receive a stress resulting from the reflowing epoxy in the high temperature and high humidity environment, thereby avoiding cracking in metal. As a result, the blowing area remains the same with the related art and the power supply is provided through the lower fuse contact 30, thereby operating in the same way as the conventional Y type fuse. Also, since the Y type fuse having the double level interconnection structure has only the lower fuse interconnection 26 to be exposed, a length of the interconnection exposed is reduced to half so that a metal crack is prevented from occurring due to strong stress in the high temperature and high humidity environment of the reliability test.

The above described fuse of the semiconductor device can be performed by the following method.

As shown in FIG. 2b, a metal layer formed over a semiconductor substrate S1 is patterned to form a metal interconnection 20. Next, an interlayer insulation layer 21 is formed over an entire upper surface including the metal interconnection 20, and a planarization etching process is performed on the interlayer insulation layer 21 so that the metal interconnection 20 is exposed. Next, an interlayer insulation layer 22 is formed over the metal interconnection 20 and the interlayer insulation layer 21 and a contact hole (not shown) is formed on the interlayer insulation layer 22. A conductive material (not shown) is formed on an overall upper surface such that the contact hole (not shown) is filled with the conductive material, and a planarizing process is performed on the conductive material (not shown) to expose the interlayer insulation layer 22 to form the lower contact 24.

As illustrated in FIG. 2c, when a lower fuse metal (not shown) is formed on an overall upper surface, a photoresist pattern (not shown) is formed on the lower fuse metal (not shown). The lower fuse metal is etched by an etch mask to form a lower fuse interconnection 26 and a lower interconnection 27. Here, a first side of the lower fuse interconnection 26 and the lower interconnection 27 are preferably connected to the lower contact 24.

As illustrated in FIG. 2d, when an insulation layer 28 is formed over an entire surface including the lower fuse interconnection 26 and the lower interconnection 27, a contact hole (not shown) connecting a second side of the lower fuse interconnection 26 and the lower interconnection 27 is formed. Next, a conductive material is formed on an overall surface including the contact hole (not shown) and a planarizing process is performed on the conductive material to expose the fuse insulation layer 28 to form the fuse contact 30.

As illustrated in FIG. 2e, an upper fuse metal (not shown) is formed on an overall surface including the fuse contact 30. Next, the upper fuse metal (not shown) is etched by using a photoresist pattern (not shown) formed on the upper fuse metal (not shown) to form an upper fuse interconnection 32 having a first and a second sides that are respectively connected to the fuse contact 30. In other words, the upper fuse interconnection 32 is formed in a manner such that the upper fuse interconnection 32 positioned above the lower fuse interconnection 26 is removed to expose the lower fuse interconnection 26 in which the fuse blowing occurs. Next, an insulation layer 34 is formed and the insulation layers 34 and 28 are etched to expose the lower fuse interconnection 26, i.e., an area in which the fuse blowing occurs. Although not shown in the drawing, the laser is applied to the exposed lower fuse interconnection 26 when blowing the fuse.

As illustrated in FIG. 3a, the fuse according to still another embodiment of the present invention includes a Y type fuse interconnection 58 having a step difference. Also, preferably, a lower contact 54 is positioned below a first and a second sides of the other side the fuse interconnection 58 and a metal interconnection 50 is positioned below the lower contact 54. In this case, the fuse interconnection 58 having the step difference includes an area A″ projected due to the step difference and an area B″ that is filled with an insulation layer 60 since the area B″ is positioned to be lower than the area A″. Here, the projected area A″ preferably has a ‘V’ shape and the area B″ filled with the insulation layer 60 preferably has a ‘T’ shape. The projected area A″ is exposed and becomes an area in which the actual fuse blowing occurs therein. Thus, the area B″ filled with the insulation layer 60 is not exposed and thus is not susceptible for a stress by the reflowing epoxy in the high temperature and high humidity environment, thereby avoiding the problem of cracking in metal. Overall, the blowing area remains the same. In addition, since only the area A″ projected due to the step difference is exposed, a length of the interconnection exposed is reduced to half so that a metal crack is prevented from occurring due to strong stress in the high temperature and high humidity environment of the reliability test.

The above described fuse of the semiconductor device can be performed by the following method.

As shown in FIG. 3b, a metal layer formed over a semiconductor substrate S2 is patterned to form a metal interconnection 50. Next, an interlayer insulation layer 51 is formed over an entire upper surface including the metal interconnection 50, and a planarization etching process is performed on the interlayer insulation layer 51 so that the metal interconnection 50 is exposed. Next, an interlayer insulation layer 52 is formed on the metal interconnection and the interlayer insulation layer 51 and a contact hole (not shown) is formed on the interlayer insulation layer 52. A conductive material (not shown) is formed on an overall upper surface such that the contact hole (not shown) is filled with the conductive material, and a planarizing process is performed on the conductive material (not shown) to expose the interlayer insulation layer 52 to form the lower contact 54.

As shown in FIG. 3c, a photoresist pattern 56 is formed to expose a portion of the interlayer insulation layer 52, and the photoresist pattern 56 is etched to a predetermined thickness using an etch mask to form a step difference c.

As shown in FIG. 3d, a fuse interconnection 58 is formed on an overall surface. Preferably, a first and a second sides of a lower part of the fuse interconnection 58 are connected to the lower contact 54, respectively. Also, when an insulation layer 60 is formed on an overall surface, the sultan layer 60 is etched to expose the fuse interconnection 58 such that an area in which blowing occurs is exposed. Preferably, the area in which the fuse interconnection 58 is exposed is an area projected due to the step difference c formed on the interlayer insulation layer 52. Although not shown in the drawing, the laser is applied to the projected fuse interconnection 58 to blow the fuse.

According to various embodiments of the present invention, the Y type fuse is prevented from receiving excessive stress due to the reflowing epoxy formed surrounding the fuse under the high temperature and high humidity condition so that the problem of metal crack can be avoided. Therefore, a blowing operation can be performed accurately, thereby increasing the yield of the semiconductor devices as well as improving characteristics thereof.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A fuse of a semiconductor device, the fuse comprising:
a Y type fuse; and
an insulation layer configured to expose the Y type fuse such that an exposed portion of the Y type fuse has a substantially ‘V’ shape.

2. The fuse of claim 1, wherein the exposed portion having the substantially ‘V’ shape corresponds to an area in which a fuse blowing occurs.

3. The fuse of claim 1, wherein the Y type fuse includes:
an upper fuse interconnection;
a lower fuse interconnection; and
a fuse contact connected to a lower part of the upper fuse interconnection and an upper part of the lower fuse interconnection.

4. The fuse of claim 3, wherein the upper fuse interconnection has a ‘V’ shape and the lower fuse interconnection has a ‘T’ shape.

5. The fuse of claim 3, wherein the upper fuse interconnection has a ‘T’ shape and the lower fuse interconnection has a ‘V’ shape.

6. The fuse of claim 5, further comprising a lower interconnection positioned on a substantially same plane with the lower fuse interconnection.

7. The fuse of claim 6, further comprising a metal interconnection positioned below the lower fuse interconnection.

8. The fuse of claim 7, further comprising a first lower contact positioned between the lower fuse interconnection and the metal interconnection.

9. The fuse of claim 1, wherein the Y type fuse includes a ‘V’ shaped area and a ‘T’ shaped area, the ‘V’ shaped area being projected by a step difference and the ‘T’ shaped area being positioned lower than the ‘V’ shaped area by the step difference.

10. The fuse of claim 9, further comprising a metal interconnection positioned below the Y type fuse.

11. The fuse of claim 10, further comprising a second lower contact that is connected to a lower part of the Y type fuse and an upper part of the metal interconnection.

12. A method of forming a fuse of a semiconductor device, the method comprising:
forming a Y type fuse; and
forming an insulation layer on the Y type fuse that exposes the Y type fuse such that an exposed portion of the Y type fuse has a substantially ‘V’ shape.

13. The method of claim 12, further comprising, after forming the insulation layer,
blowing the Y type fuse that is exposed in the substantially ‘V’ shape.

14. The method of claim 12, wherein the forming the Y type fuse includes:
forming a lower fuse interconnection;
forming a fuse contact on the lower fuse interconnection; and
forming an upper fuse interconnection that is connected to an upper part of the fuse contact.

15. The method of claim 14, wherein, in the forming the insulation layer, the upper fuse interconnection is exposed such that an exposed portion of the upper fuse interconnection has a substantially ‘V’ shape.

16. The method of claim 14, wherein, in the forming the insulation layer, the lower fuse interconnection is exposed such that an exposed portion of the lower fuse interconnection has a substantially ‘V’ shape.

17. The method of claim 16, further comprising, at the same time as the forming the lower fuse interconnection,
forming a lower interconnection that is on a substantially same plane with the lower fuse interconnection.

18. The method of claim 17, further comprising, prior to the forming the lower fuse interconnection,
forming a metal interconnection; and
forming a first lower contact on the metal interconnection, the first lower contact being connected with the lower fuse interconnection and the lower interconnection.

19. The method of claim 12, wherein the forming the Y type fuse includes:
forming an interlayer insulation layer having a step difference; and
forming a fuse interconnection on the interlayer insulation layer.

20. The method of claim 19, further comprising, prior to the forming the Y type fuse,
forming a metal interconnection; and
forming a second lower contact on the metal interconnection, the second lower contact being connected with the Y type fuse.
